(19) United States
(12) Patent Application Publication
(10) Pub. No.: US 2025/0372734 A1
(43) Pub. Date: Dec. 4, 2025

(54) BUS CONNECTOR FOR AN ENERGY STORAGE SYSTEM

(71) Applicant: Cox Automotive, Inc., Atlanta, GA (US)

(72) Inventor: Connor Benjamin Taylor, Norman, OK (US)

(73) Assignee: Cox Automotive, Inc., Atlanta, GA (US)

(21) Appl. No.: 18/680,814

(22) Filed: May 31, 2024

(51) Int. Cl. H01M 10/42; H01M 10/48; H01M 50/519; H01R 4/34; H02J 7/00; H05K 1/18

(52) U.S. Cl. CPC H01M 10/425; H01M 10/482; H01M 10/486; H01M 50/519; H01R 4/34; H02J 7/0047; H02J 7/0063; H02J 7/007194; H05K 1/18; H05K 2201/10151

(57) ABSTRACT

A bus connector for an energy storage system is provided. The bus connector includes a printed circuit board including a first plurality of metal plates, a second plurality of metal plates, a plurality of bus taps, a plurality of conducting stripes, and a temperature sensor. The first plurality of metal plates is coupled to first terminals of the first battery module. The second plurality of metal plates is coupled to second terminals of the second battery module. Each of the first plurality of metal plates, each of the second plurality of metal plates, and the temperature sensor are connected to a respective bus tap of the plurality of bus taps through a respective conducting stripe of the plurality of conducting stripes. The temperature sensor is configured to sense a temperature of at least one of the first battery module and the second battery module.

### BACKGROUND

Environmental impact of non-renewable energy sources such as coal, petroleum, natural gas, and the like has led to an increased popularity of electric vehicles and hybrid-electric vehicles among the general population. Further, renewable energy sources such as solar power, wind power, hydro-electric power, geothermal power, and the like are also gaining a strong foothold in the energy sector. Electric and hybrid-electric vehicles, wind power systems, electric grids, as well as solar power systems typically employ electrochemical devices for storing energy for later consumption. The electrochemical devices are also employed in devices such as household appliances, medical device, power tools, consumer electronics, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a diagram of An Energy Storage System (ESS).

FIG. 2 is a diagram illustrating battery modules of a battery pack.

FIG. 3A is a diagram of a first battery module.

FIG. 3B is diagram illustrating an example cell configuration of the first battery module.

FIG. 4 is a diagram illustrating sections of a battery pack.

FIG. 5 is a diagram illustrating a bus connector.

FIG. 6 is a diagram illustrating a temperature sensor.

FIG. 7 is a partial block diagram and a partial circuit diagram illustrating a contact weld detector.

FIG. 8 is a flow diagram of a method of determining a status of a contact.

FIG. 9 is a block diagram of a computing device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Electrochemical devices, for example, a rechargeable battery, a storage battery, a secondary cell, or an accumulator is a type of electrical battery that can be charged, discharged into a load, and recharged many times. The rechargeable batteries are used in energy storage systems for storing energy for later consumption. For example, wind power systems, electric grids, as well as solar power systems typically employ energy storage systems for storing energy for later consumption. The energy storage systems are also employed in devices such as household appliances, medical device, power tools, consumer electronics, and the like.

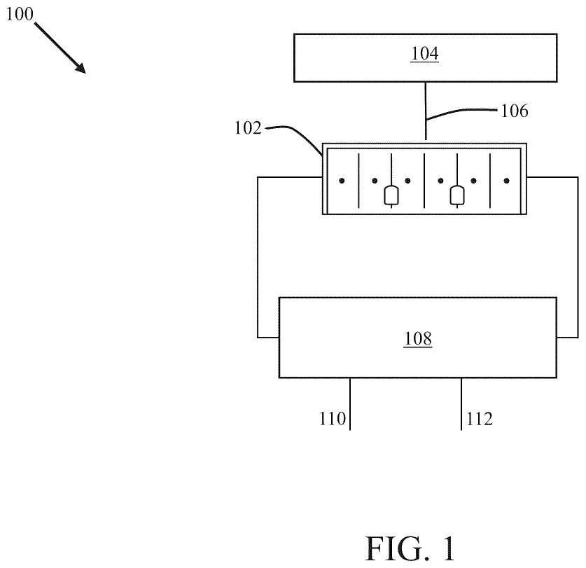

FIG. 1 is a block diagram of an Energy Storage System (ESS) 100. As shown in FIG. 1, ESS 100 includes a battery pack 102 and a controller 104. Controller 104 is connected to battery pack 102 through a communication bus 106. Battery pack 102 may be connected to a conversion unit 108. Conversion unit 108 can connect battery pack 102 to a charging source, a load, or both a charging source and a load through a first terminal 110 and a second terminal 112. In some other examples, controller 104 may be part of conversion unit 108. In some other examples, conversion unit 108 is not a part of ESS 100.

Battery pack 102 is an electrochemical device, for example, a rechargeable battery. Battery pack 102 stores energy for later consumption. Battery pack 102 may include a plurality of battery modules connected together. In examples, a battery module may be the smallest unit of battery pack 102 without breaking any permanent mechanical systems. In some embodiments, these battery modules may be manufactured for or recovered from one or more battery packs of a vehicle, for example, an electric vehicle.

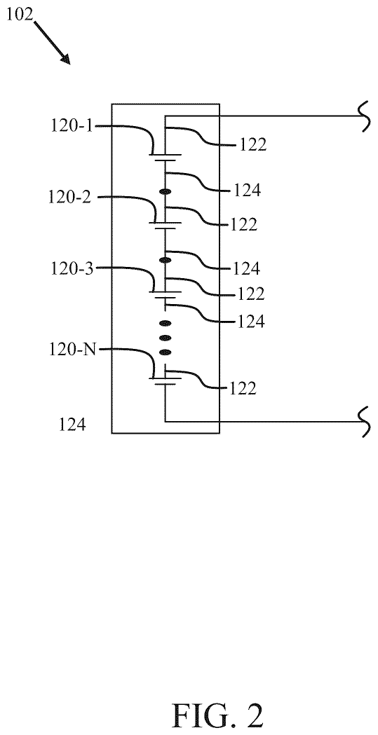

FIG. 2 illustrates an example battery pack 102. As shown in FIG. 2, battery pack 102 may include a plurality of battery modules, that is, a first battery module 120-1, a second battery module 120-2, a third battery module 120-3, . . . , an Nth battery module 120-N connected together. It may be understood that battery pack 102 may include any number of battery modules. For example, battery pack 102 may include 2, 3, 4, 5, 10, 20, 30, or 40, battery modules.

Each of the plurality of battery modules have a positive terminal 122 and a negative terminal 124. The plurality of battery modules can be combined in a series configuration in which positive terminal 122 of one of the plurality of battery modules is connected to negative terminal 124 of an adjacent battery module. In some arrangement, one or more battery modules are connected in parallel while some battery modules are connected in series. A total capacity and voltage rating of battery pack 102 may depend on a number of battery modules included in battery pack 102 and the connection configuration of the battery modules.

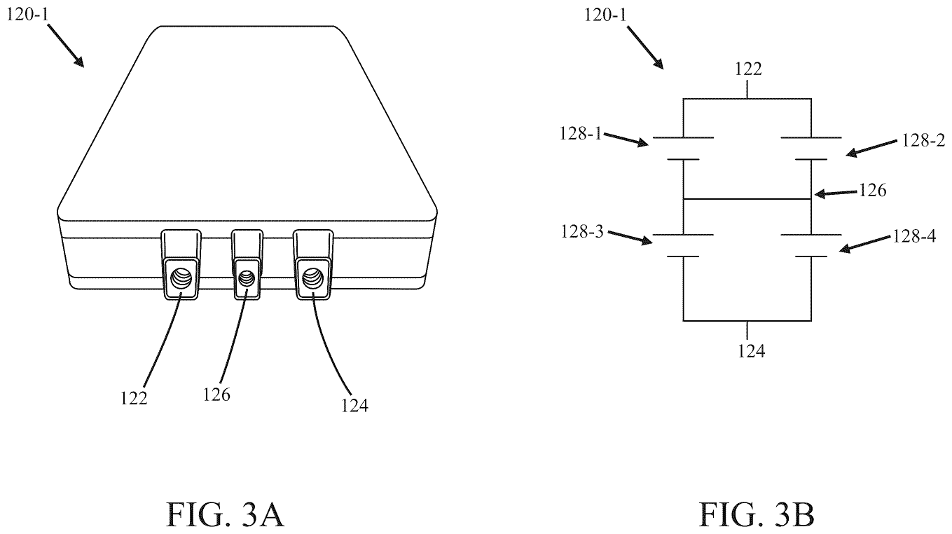

FIG. 3A is a diagram of first battery module 120-1. FIG. 3B is a diagram illustrating an example cell configuration of first battery module 120-1. As shown in FIGS. 3A and 3B, first battery module 120-1 may include positive terminal 122 and negative terminal 124. In addition, first battery module 120-1 may include a center terminal 126 (also referred to as an intermediate voltage terminal). Moreover, first battery module 120-1 may include four cells, that is, first cell 128-1, second cell 128-2, third cell 128-3, and fourth cell 128-4. First cell 128-1 and second cell 128-2 are connected in parallel to each other between positive terminal 122 and center terminal 126. Third cell 128-3 and fourth cell 128-4 are connected in parallel to each other between center terminal 126 and negative terminal 124. The pair of parallel connected cells are then connected in series. Thus, the cell configuration shown in FIG. 3B is also referred to as 2p2s configuration.

Although, first battery module 120-1 is shown to include four cells, it may include a different number of cells, for example, 2, 3, 5, etc. In addition, although first battery module 120-1 is shown to be in 2p2s configuration, first battery module 120-1 may include a different type of configuration. A capacity and voltage rating of first battery module 120-1 may depend on a number of battery cells included in first battery module 120-1 and connection configuration of the battery cells.

In some examples, one or more fuses may divide battery pack 102 into two or more sections or groupings. Battery sections are generally composed of a plurality of modules and may be structured for ease in disassembly and reconstituted through the use of removable hardware (e.g., threaded rods with removable nuts). These structures may arise for two reasons. First is the requirement for mechanical compression which may be required for proper functioning. Second, intermediate electrical equipment, such as fuses and contactors, are positioned for safety and operation. For example, fuses are typically located mid-battery pack so that removal of the fuse reduces battery voltage by half.

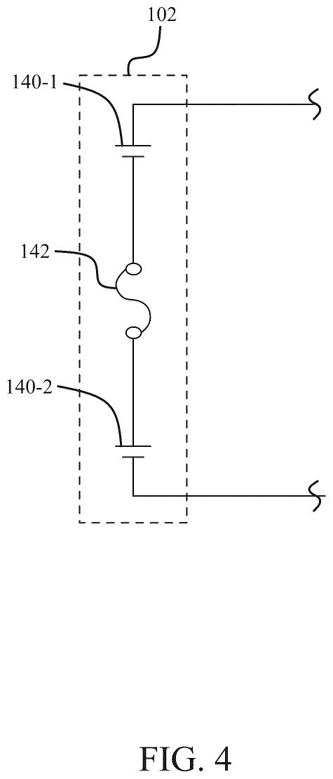

FIG. 4 is a diagram illustrating sections of battery pack 102. As shown in FIG. 4, battery pack 102 includes two sections, a first section 140-1 and a second section 140-2 connected by a fuse 142. Each of first section 140-1 and second section 140-2 may include multiple battery modules, for example, 2, 3, 4, 5, 10, 15, 20, 30, 40, etc. A number of battery modules in each of first section 140-1 and second section 140-2 may be the same or different depending on a design consideration of battery pack 102. In addition, battery pack 102 may include more than two modules and the modules do not have to be separated by fuse 142. Moreover, in some examples, if present, fuse 142 does not have to be between sections, and can be located anywhere along a current path. For example, fuse 142 can be located anywhere on exterior of battery pack 102 so that fuse 142 is more accessible by a user.

Referring back to FIG. 1, controller 104 determines a status of and controls the operation of battery pack 102. Controller 104 is connected to battery pack 102 through communication bus 106. Controller 104 receives status signals from battery pack 102 and can send control signals to battery pack 102 over communication bus 106. In some examples, communication bus 106 is a serial communication bus such as a Modbus Remote Terminal Unit (RTU) over RS-485, or Controller Area Network (CAN) bus, and the like. In some examples, controller 104 may be part of conversion unit 108. In some examples, controller 104 includes a power cycler.

Conversion unit 108 may be one of a Direct Current (DC)-DC converter or a DC-Alternating Current (AC) inverter, or a dual convertor comprising both DC-DC converter and DC-AC convertor. In one example, conversion unit 108 receives a first voltage from battery pack 102 and generates a second voltage as a DC or an AC voltage at first terminal 110 and second terminal 112. In another example, conversion unit 108 receives a first voltage from a renewable energy source or an electric grid and converts that voltage into a second voltage as a DC voltage to charge battery pack 102. First terminal 110 and second terminal 112 of conversion unit 108 are connected to at least one of a load, an electric grid, and a micro-grid.

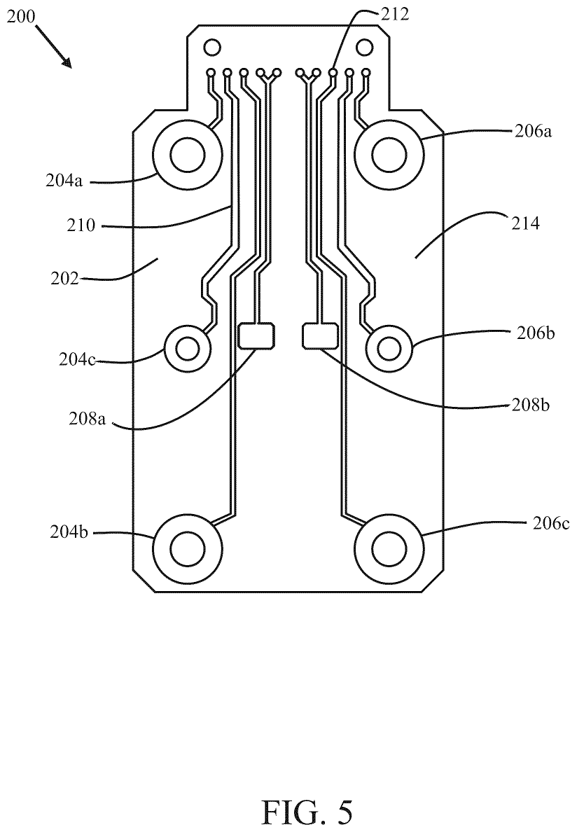

FIG. 5 is a diagram illustrating a bus connector 200. Bus connector 200 may be connected to two adjacent battery modules of battery pack 102 and provide a connection point from the two adjacent battery modules to communication bus 106. As shown in FIG. 5, bus connector 200 may include a printed circuit board 202. In an example embodiment, printed circuit board 202 includes a first plurality of metal plates (that is, a first metal plate 204a, a second metal plate 204b, and a third metal plate 204c) and a second plurality of metal plates (that is, a fourth metal plate 206a, a fifth metal plate 206b, and a sixth metal plate 206c). In addition, printed circuit board 202 includes a plurality of temperature sensors (that is, a first temperature sensor 208a and a temperature second sensor 208b. Each of the first plurality of metal plates, the second plurality of metal plates, and the plurality of temperature sensors are connected through a respective conducting stripe of a plurality of conducting stripes 210 to a respective tap in bus taps 212. Bus taps 212 can be connected to communication bus 106. Plurality of conducting stripes 210 are located between the first plurality of metal plates and the second plurality of metal plates. Plurality of conducting stripes 210 are formed on a first surface 214 of printed circuit board 202. A second surface 216 of printed circuit board 202 is opposite of first surface 214.

The first plurality of metal plates 204a-c may be located closer to a first side of printed circuit board 202. The second plurality of metal plates 206a-c may be located closer to a second side of printed circuit board 202, the second side being opposite to the first side. Each of the first plurality of metal plates and the second plurality of metal plates may extend from first surface 214 to second surface 216 of printed circuit board 202.

In one example, each of the first plurality of metal plates 204a-c and the second plurality of metal plates 206a-c are circular with an opening in the center. The opening of each of first metal plate 204a, third metal plate 204c, fourth metal plate 206a, and sixth metal plate 206c may have a first diameter. The first diameter is sized to receive a bolt shaft of a fastener sized to fit into positive terminal 122 or negative terminal 124 of a battery module, for example, first battery module 120-1. An opening of each of second metal plate 204b and fifth metal plate 206b may have a second diameter. The second diameter is sized to receive a bolt shaft of another fastener sized to fit into center terminal 126 of first battery module 120-1. In examples, the second diameter is smaller than the first diameter. In addition, a diameter of each of first metal plate 204a, third metal plate 204c, fourth metal plate 206a, and sixth metal plate 206c may be greater than a diameter of each of second metal plate 204b and fifth metal plate 206b. The first plurality of metal plates and the second plurality of metal plates may prevent loosening of fasteners, may increase or distribute a load of a fastener, and may protect joint surfaces of battery pack 102. In some examples, the first plurality of metal plates and the second plurality of metal plates may not be circular.

Printed circuit board 202 includes a body portion and a neck portion. The first plurality of metal plates and the second plurality of metal plates are located in the body portion. Bus taps 212 are located in the neck portion.

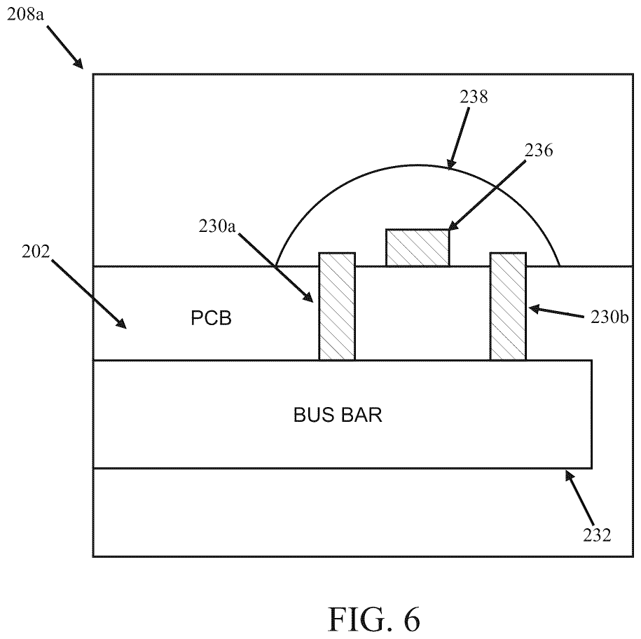

FIG. 6 is a diagram of first temperature sensor 208a. As shown in FIG. 6, first temperature sensor 208a includes a first metal contactor 230a and a second metal contactor 230b. Each of first metal contactor 230a and second metal contactor 230b may have a first end at first surface 214 and a second end at second surface 216 of printed circuit board 202. The second end of each of first metal contactor 230a and second metal contactor 230b may contact a bus bar 232 associated with a battery module, for example, first battery module 120-1. A sensing unit 236 is placed equidistance from the first end of each of first metal contactor 230a and second metal contactor 230b on first surface 214 of printed circuit board 202. Sensing unit 236 is covered with an epoxy layer 238. In some examples, sensing unit 236 and the first ends of first metal contactor 230a and second metal contactor 230b are covered with an epoxy layer 238. Epoxy layer 238 may increase accuracy and efficiency of sensing unit 236.

First metal contactor 230a and second metal contactor 230b transfer heat from bus bar 232 to first surface 214 of printed circuit board 202. Sensing unit 236 can then sense a temperature of bus bar 232 and by extension of battery module 120 without being in direct contact with bus bar 232. Thus, sensing unit 236 is electrically isolated from bus bar 232.

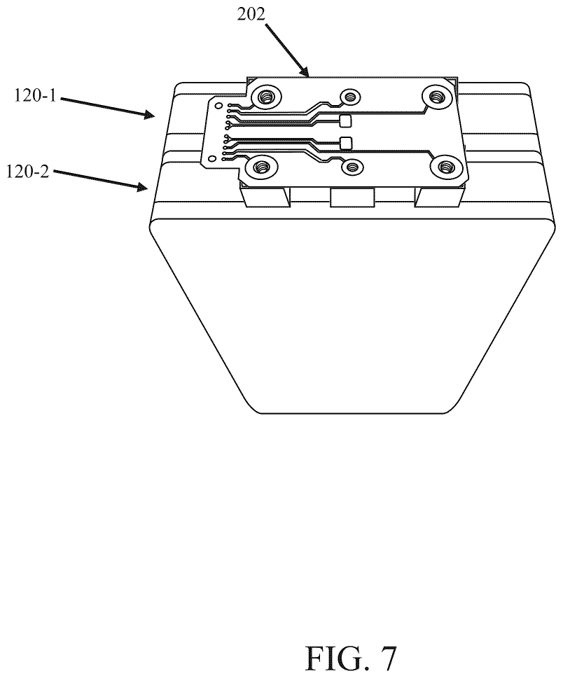

Bus connector 200 may be connected to two adjacent battery modules of battery pack 102. FIG. 7 is a diagram of illustrating bus connector 200 being connected to first battery module 120-1 and second battery module 120-2. As shown in FIG. 7, the first plurality of metal plates of printed circuit board 202 are connected to first terminals of first battery module 120-1 and the second plurality of metal plates of printed circuit board 202 are connected to second terminals of second battery module 120-2.

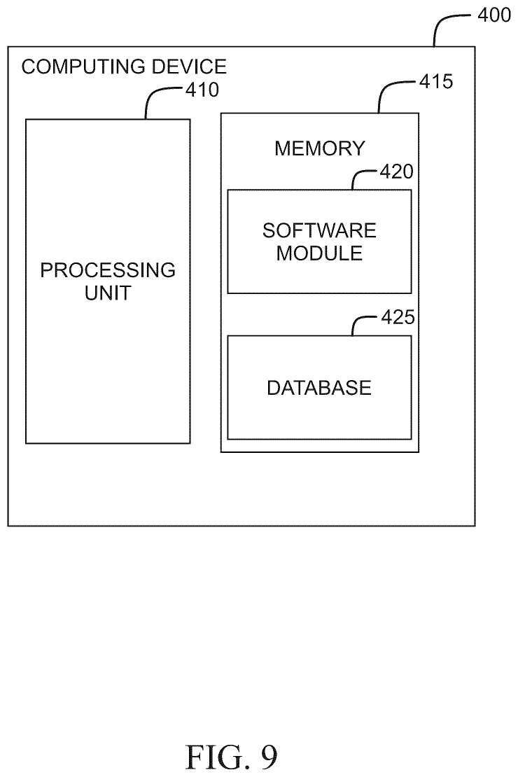

The elements described above of ESS 100 (e.g., controller 104, conversion unit 108, and sensing unit 236) may be practiced in hardware and/or in software (including firmware, resident software, micro-code, etc.) or in any other circuits or systems. The elements of ESS 100 may be practiced in electrical circuits comprising discrete electronic elements, packaged or integrated electronic chips containing logic gates, a circuit utilizing a microprocessor, or on a single chip containing electronic elements or microprocessors. Furthermore, the elements of ESS 100 may also be practiced using other technologies capable of performing logical operations such as, for example, AND, OR, and NOT, including but not limited to, mechanical, optical, fluidic, and quantum technologies. As described in greater detail below with respect to FIG. 9, the elements of ESS 100 may be practiced in a computing device 400.

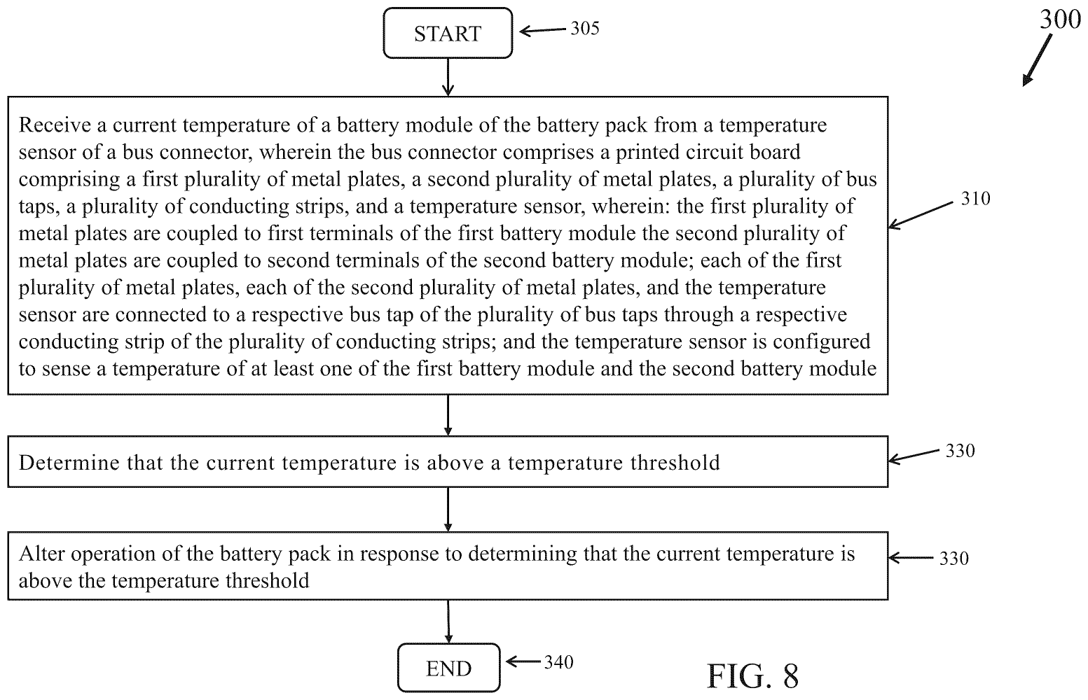

FIG. 8 is a flow chart setting forth the general stages involved in a method 300 consistent with an embodiment of the disclosure for monitoring battery pack 102. Method 300 may be performed by controller 104. Ways to implement the stages of method 300 will be described in greater detail below.

Method 300 begins at starting block 305 and proceeds to stage 310 where controller 104 receives a current temperature of a battery module (for example, first battery module 120-1) of battery pack 102 from a temperature sensor (for example, first temperature sensor 208a) of bus connector 200. As discussed above, bus connector 200 includes printed circuit board 202 including a first plurality of metal plates, a second plurality of metal plates, plurality of bus taps 212, plurality of conducting stripes 210, and first temperature sensor 208a. The first plurality of metal plates is coupled to first terminals of first battery module 120-1. The second plurality of metal plates is coupled to second terminals of second battery module 120-2. Each of the first plurality of metal plates, each of the second plurality of metal plates, and the temperature sensor are connected to a respective bus tap of plurality of bus taps 212 through a respective conducting stripe of plurality of conducting stripes 210. The temperature sensor is configured to sense a current temperature of at least one of first battery module 120-1 and second battery module 120-2. Controller 104 receives the current temperature from the temperature sensor.

After receiving the current temperature at stage 310, method 300 proceeds to block 320 where controller 104 determines that the current temperature is above a temperature threshold. The temperature threshold can be predetermined. In some examples, the temperature threshold can be predetermined by a manufacturer of the battery module.

Once having determined that the current temperature is above the temperature threshold at block 320, method 300 proceeds to stage 330 where controller 104 alters operation of battery pack 102 in response to determining that the current temperature is above the temperature threshold. For example, controller 104 may reduce a load on battery pack 102 if the current temperature is more than the threshold. In some examples, controller 104 may disconnect a load from battery pack 102 if the current temperature is more than the threshold. After altering operation of the battery pack at stage 330, method 300 may terminate at end block 340.

In some examples, controller 104 may receive a current voltage measurement of the battery module and altering the operation the battery pack in response to determining that the current temperature is below the voltage threshold. In some other examples, controller 104 may determine a rate of change of the current temperature of the battery module and determine a status of the battery module based on the rate of change of the current temperature. For example, if the temperature of battery pack 102 is rising faster than a predetermined rate, controller 104 may reduce a load or disconnect the load from battery pack 102.

FIG. 9 shows computing device 400. As shown in FIG. 9, computing device 400 includes a processing unit 410 and a memory unit 415. Memory unit 415 includes a software module 420 and a database 425. While executing on processing unit 410, software module 420 performs, for example, processes for monitoring battery pack 102, including for example, any one or more of the stages from method 300 described above with respect to FIG. 8. Computing device 400, for example, provides an operating environment for controller 104 and conversion unit 108. Controller 104 and conversion unit 108 may operate in other environments and are not limited to computing device 400.

Computing device 400 can be implemented using a tablet device, a mobile device, a smart phone, a telephone, a remote control device, a personal computer, a network computer, a mainframe, a router, a switch, a server cluster, a smart TV-like device, a network storage device, a network relay device, or other similar microcomputer-based device. Computing device 400 can include any computer operating environment, such as hand-held devices, multiprocessor systems, microprocessor-based or programmable sender electronic devices, minicomputers, mainframe computers, and the like. Computing device 400 can also be practiced in distributed computing environments where tasks are performed by remote processing devices. The aforementioned systems and devices are examples and computing device 400 can comprise other systems or devices.

Embodiments of the disclosure, for example, can be implemented as a computer process (method), a computing system, or as an article of manufacture, such as a computer program product or computer readable media. The computer program product can be a computer storage media readable by a computer system and encoding a computer program of instructions for executing a computer process. The computer program product can also be a propagated signal on a carrier readable by a computing system and encoding a computer program of instructions for executing a computer process. Accordingly, the present disclosure can be embodied in hardware and/or in software (including firmware, resident software, micro-code, etc.). In other words, embodiments of the present disclosure can take the form of a computer program product on a computer-usable or computer-readable storage medium having computer-usable or computer-readable program code embodied in the medium for use by or in connection with an instruction execution system. A computer-usable or computer-readable medium can be any medium that can contain, store, communicate, propagate, or transport the program for use by or in connection with the instruction execution system, apparatus, or device.

The computer-usable or computer-readable medium can be, for example but not limited to, an electronic, magnetic, optical, electromagnetic, infrared, or semiconductor system, apparatus, device, or propagation medium. More specific computer-readable medium examples (a non-exhaustive list), the computer-readable medium can include the following: an electrical connection having one or more wires, a portable computer diskette, a random access memory (RAM), a read-only memory (ROM), an erasable programmable read-only memory (EPROM or Flash memory), an optical fiber, and a portable compact disc read-only memory (CD-ROM). Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

While certain embodiments of the disclosure have been described, other embodiments may exist. Furthermore, although embodiments of the present disclosure have been described as being associated with data stored in memory and other storage mediums, data can also be stored on or read from other types of computer-readable media, such as secondary storage devices, like hard disks, or a CD-ROM, a carrier wave from the Internet, or other forms of RAM or ROM. Further, the disclosed methods' stages may be modified in any manner, including by reordering stages and/or inserting or deleting stages, without departing from the disclosure.

Furthermore, embodiments of the disclosure may be practiced in an electrical circuit comprising discrete electronic elements, packaged or integrated electronic chips containing logic gates, a circuit utilizing a microprocessor, or on a single chip containing electronic elements or microprocessors. Embodiments of the disclosure may also be practiced using other technologies capable of performing logical operations such as, for example, AND, OR, and NOT, including but not limited to, mechanical, optical, fluidic, and quantum technologies. In addition, embodiments of the disclosure may be practiced within a general purpose computer or in any other circuits or systems.

Embodiments of the disclosure may be practiced via a system-on-a-chip (SOC) where each or many of the element illustrated in FIGS. 1-5 may be integrated onto a single integrated circuit. Such a SOC device may include one or more processing units, graphics units, communications units, system virtualization units and various application functionality all of which may be integrated (or “burned”) onto the chip substrate as a single integrated circuit. When operating via a SOC, the functionality described herein with respect to embodiments of the disclosure, may be performed via application-specific logic integrated with other components of computing device 400 on the single integrated circuit (chip).

Embodiments of the present disclosure, for example, are described above with reference to block diagrams and/or operational illustrations of methods, systems, and computer program products according to embodiments of the disclosure. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

While the specification includes examples, the disclosure's scope is indicated by the following claims. Furthermore, while the specification has been described in language specific to structural features and/or methodological acts, the claims are not limited to the features or acts described above. Rather, the specific features and acts described above are disclosed as example for embodiments of the disclosure.

What is claimed is:

1. A bus connector for an energy storage system, the bus connector comprising:
a printed circuit board comprising a first plurality of metal plates, a second plurality of metal plates, a plurality of bus taps, a plurality of conducting stripes, and a temperature sensor, wherein:
the first plurality of metal plates is located on a first side of the printed circuit board, the first plurality of metal plates spaced and sized to receive and be coupled to first terminals of a first battery module;
the second plurality of metal plates is located on a second side of the printed circuit board, the second plurality of metal plates spaced and sized to receive and be coupled second terminals of a second battery module;
each of the first plurality of metal plates, each of the second plurality of metal plates, and the temperature sensor are connected to a respective bus tap of the plurality of bus taps through a respective conducting stripe of the plurality of conducting stripes; and
the temperature sensor is configured to sense a temperature of at least one of the first battery module and the second battery module.

2. The bus connector of claim 1, wherein the temperature sensor comprises:
a first metal contactor;
a second metal contactor spaced from the first metal contactor; and
a sensing unit positioned between the first metal contactor and the second metal contactor.

3. The bus connector of claim 2, wherein:
a first end of each of the first metal contactor and the second metal contactor is located at a first surface of the printed circuit board;
a second end of each of the first metal contactor and the second metal contactor is located at a second surface of the printed circuit board, the second surface being opposite of the first surface; and
the sensing unit is located at the first surface of the printed circuit board.

4. The bus connector of claim 3, wherein the sensing unit is enveloped by an epoxy layer.

5. The bus connector of claim 3, wherein the second end of each of the first metal contactor and the second metal contactor is in contact with a bus bar connected to at least one of the first battery module and the second battery module.

6. The bus connector of claim 3, wherein the plurality of conducting stripes are formed on the first surface of the printed circuit board.

7. The bus connector of claim 1, wherein each of the first plurality of metal plates comprises an opening at the center, wherein a diameter of the opening is sized to receive a respective fastener for connected a bus bar to a respective metal plate.

8. The bus connector of claim 1, wherein the printed circuit board further comprises a body portion and a neck portion, wherein the first plurality of metal plates and the second plurality of metal plates are located in the body portion, and wherein the plurality of bus taps is located in the neck portion.

9. The bus connector of claim 1, wherein the temperature sensor is electrically isolated from current carrying components.

10. A battery pack comprising:
a first battery module;
a second battery module connected to first battery module through at least one bus bar;
a printed circuit board comprising a first plurality of metal plates, a second plurality of metal plates, a plurality of bus taps, a plurality of conducting stripes, and a temperature sensor, wherein:
the first plurality of metal plates is coupled to first terminals of the first battery module;
the second plurality of metal plates is coupled to second terminals of the second battery module;
each of the first plurality of metal plates, each of the second plurality of metal plates, and the temperature sensor are connected to a respective bus tap of the plurality of bus taps through a respective conducting stripe of the plurality of conducting stripes; and
the temperature sensor is configured to sense a temperature of at least one of the first battery module and the second battery module.

11. The battery pack of claim 10, wherein the temperature sensor is electrically isolated from current carrying components.

12. The battery pack of claim 10, wherein at least one of the first battery module and the second battery module is recovered from a vehicle battery pack.

13. The battery pack of claim 10, further comprising a controller connected to the plurality of bus taps through a bus bar.

14. The battery pack of claim 13, wherein the controller is configured to determine a status of the battery pack based on the sensed temperature.

15. The battery pack of claim 13, further comprising a load connected to the battery pack, wherein the controller is configured to control an amount of power being provided to the load based on the sensed temperature.

16. The battery pack of claim 10, wherein the first plurality of metal plates comprises a first metal plate, a second metal plate, and third metal plate, and wherein first metal plate and the third metal plate are bigger than the second metal plate.

17. The battery pack of claim 16, wherein each of the first plurality of metal plates comprises an opening at the center, wherein a first diameter of the opening of each of the first metal plate and the third metal plate is greater than a second diameter of the opening of the second metal plate.

18. A method of monitoring a battery pack, the method comprising:
receiving a current temperature of a battery module of the battery pack from a temperature sensor of a bus connector, wherein the bus connector comprises a printed circuit board comprising a first plurality of metal plates, a second plurality of metal plates, a plurality of bus taps, a plurality of conducting stripes, and a temperature sensor, wherein:
the first plurality of metal plates is coupled to first terminals of the first battery module;
the second plurality of metal plates is coupled to second terminals of the second battery module;
each of the first plurality of metal plates, each of the second plurality of metal plates, and the temperature sensor are connected to a respective bus tap of the plurality of bus taps through a respective conducting stripe of the plurality of conducting stripes; and
the temperature sensor is configured to sense a temperature of at least one of the first battery module and the second battery module;
determining that the current temperature is above a temperature threshold; and
altering operation the battery pack in response to determining that the current temperature is above the temperature threshold.

19. The method of claim 18, further comprising:
receiving a current voltage measurement of the battery module; and
altering the operation the battery pack in response to determining that the current temperature is below the voltage threshold.

20. The method of claim 18, further comprising:
determining a rate of change of the current temperature of the battery module; and
determining a status of the battery module based on the rate of change of the current temperature.
